(19) United States
(12) Patent Application Publication
(10) Pub. No.: US 2015/0050491 A1
(43) Pub. Date: Feb. 19, 2015

(54) METHOD FOR PRODUCING A TEXTURED SPINEL IRON OXIDE LAYER

(71) Applicant: COMMISSARIAT A L'ENERGIE ATOMIQUE ET AUX ENE ALT, Paris (FR)

(72) Inventors: Xavier Zucchi, Vaulnaveys-le-haut (FR); Marc Guillaumont, Grenoble (FR)

(73) Assignee: COMMISSARIAT A L'ENERGIE ATOMIQUE ET AUX ENE ALT, Paris (FR)

(21) Appl. No.: 14/459,472

(22) Filed: Aug. 14, 2014

(30) Foreign Application Priority Data
Aug. 16, 2013 (FR) 13 58036

(51) Int. Cl. H01F 41/14; C23C 14/08; C23C 16/40

(52) U.S. Cl. CPC H01F 41/14; C23C 16/406; C23C 14/085
USPC 428/336; 427/131

(57) ABSTRACT

The invention relates to a method for producing a spinel iron oxide layer. textured according to a preferred crystal orientation along the [111] direction, with the spinel iron oxide layer being a ferrite layer or a doped ferrite layer, characterised in that it comprises:
producing a bottom layer of titanium (Ti) or titanium oxide (TiOx), with the thickness of the bottom layer being greater than or equal to eight nanometres;
producing a spinel iron oxide layer on the bottom layer produced beforehand.
   It also relates to a device comprising a layer of textured ferrite.

### TECHNICAL FIELD OF THE INVENTION

The present invention generally relates to the texturing of materials used by the microelectronics and microsystems industry and more particularly the texturing of spinet iron oxides.

### STATE OF THE ART

Obtaining the texturing of the materials used is often desired for many applications in microelectronics and more generally for the production of microsystems.

Texturing, here, means the ordered characteristic of the crystallographic structure which such materials can gain. The most current example is silicon the physical and electric properties of which are significantly different, depending on the state thereof: single-crystal, wherein only one crystalorientation is present; polycrystalline, wherein the grains of a polycrystalline sample may have a marked crystal orientation but wherein the latter may also be randomly oriented relative to one another as this is the case for a powder; and eventually amorphous, wherein no crystal orientation can be detected, with the amorphous state corresponding to the case where the material is not crystallised at all.

A range of materials likely to be adapted to numerous applications in microelectronics is that of iron oxides which can be found as various chemical products. A part thereof, currently called spinel iron oxides, revealed particularly adapted to the implementation of miscellaneous devices such as the non volatile memories (FeRAM), conductive-bridging resistive memories (CBRAM), infrared photodetectors, and to other applications taking advantage of their magnetic characteristic, for instance spintronics.

This more particularly relates to magnetite the chemical composition of which is Fe3O4 and maghemite the chemical composition of which is Fe2O3 in its so-called gamma phase (γ-Fe2O3).

Texturing a spinel iron oxide layer makes it possible to confer properties which are liable to significantly improve the operation of the devices wherein such layers are used.

For most of the spinel iron oxide (for example Fe₃O₄), the growth direction to be favoured, in the ecase of magnetism, is the crystalline [111] direction (or <111> taking into account all of the directions). The coefficients specified in square brackets correspond to direction index. The notation used for the texture is (111) (or {111} taking into account all of the crystalline planes), where indices into brackets correspond to Miller indices, that is the conventional way to call the planes in a crystal.

These notations, using direction indices and Miller indices, are widely used by the whole microelectronic industry and is well known by the person skilled in the art.

Indeed, the [111] direction is called “axis of easy magnetization” in the literature, axis along which it is easier to align the magnetization for these compounds.

The table hereunder gives the physical properties of magnetite and maghemite for a better understanding of the invention.

| | Magnetite | Maghemite |
|---|---|---|
| | Fe₃O₄ | γ-Fe₂O₃ |
| Mesh parameter in nm | 0.8936 | 0.83474 |
| (10⁻⁹ metre): | | |
| Density | 5.18 | 4.87 |
| Type and resistivity at | Semi-conducting | Insulating |
| 300° K in Ohm · cm: | 5 × 10⁻³ | 1 × 10¹⁹ |
| Type of magnetism: | Ferrimagnetic | Ferrimagnetic |

Magnetite and maghemite can be formed using many known techniques and more particularly:
oxydation of less oxidized phases (Fe or FeO);
by MBE, the acronym for <<molecular beam epitaxy>> i.e. a technique consisting in sending one or more molecular jet(s) onto a substrate previously selected to make an epitaxial growth;
by PLD, the acronym for <<pulsed laser deposition>> which is a method of thin film deposition using a high intensity laser beam also called a <<pulsed laser ablation>> and which makes it possible to sputter the atoms of a target which are going to condense on a substrate;
by magnetron cathodic sputtering;
by IBD, the acronym for <<ion beam deposition>>:
by ultrasonic spray pyrolysis according to the so-called <<sol-gel>> technique

To obtain a textured magnetite or maghemite layer, the known solutions start from under-layers made of materials such as: sapphire (Al₂O₃); silicon (Si); gallium arsenide (GaAs); copper (Cu); ruthenium (Ru); strontium titanate SrTiO₃; zinc oxide (ZnO); platinum (Pt) and more particularly magnesium oxide (MgO).

For example, the publication entitled <<Atomic and electronic structure of the Fe₃O₄(111)/MgO(111) model polar oxide interface>> by V. K. Lazarov, M. Weinert, S. A. Chambers, M. Gajdardziska-Josifovska, published in 2005 in the <<Physical Review B 72>> published by <<The American Physical Society>>, recommends to obtain a magnetite layer (Fe₃O₄) the crystalline structure of which is (111)-oriented by epitaxial growing from a magnesium oxide (MgO) layer.

It should be noted that, to obtain the texturing of magnetite, the magnesium oxide under-layer must be mono-crystalline, and have an (111) orientation. This necessarily implies constraints as regards the method.

More particularly, this solution requires to obtain a single-crystal magnesium oxide <<bulk substrate>>, which is expensive, and in practice induces a limitation of the size of the substrate. In addition, it is impossible to obtain complex or <<MEMS>>, the acronym for <<microelectromechanical systems>> stackings which refers to microelectromechanical systems, and no conventional microelectronics equipment can define patterns on this type of substrate.

An alternative solution consists in using a thin textured (111) layer in contact with the spinel iron oxide layer. However, this requires to orientate such thin layer beforehand, using underlying crystalline substrates, which have also been carefully oriented. This alternative solution is thus very expensive too and always raises problems as regards the making of complex stackings and MEMS, even though the definition of patterns by conventional equipment is then possible anyway.

It should also be noted that, in order to obtain the texturing of the magnesium oxide layer (MgO) with a crystal (111) orientation, high temperatures must be implemented in a range from 500° C. to 800° C. Such temperatures are not compatible with the presence of a circuit underlying the spinet iron oxide layer.

The underlying circuit is typically an integrated circuit (IC), for example of the CMOS type, the acronym for <<complementary metal-oxide-semiconductor>>, which refers to the most commonly produced type of electronic circuits at present, by the microelectronics industry.

As texturing must be executed in a layer located above a circuit and requires temperatures from 500° C. to 800° C., the manufacturing of the device thus becomes complex and thus very expensive. As a matter of fact methods for transferring previously structured layers should then be implemented to obtain this result. All the more so since the integrated circuit itself is already interconnected, i.e. has gone through the so-called <<BEOL>>, the acronym for <<back-end of line>> manufacturing steps and high temperature which might damage it can no longer be implemented.

Therefor a need exists which consists in limiting or even in eliminating at least some of the drawbacks of the known solutions to obtain a spinel iron oxide layer textured in the growth [111] direction.

### SUMMARY OF THE INVENTION

To reach this objective, one aspect of the present invention relates to a method for manufacturing a spinet iron oxide layer (also called a spinel structure iron oxide), textured along a preferred crystal orientation in the [111] direction, with the spinel iron oxide layer being a ferrite layer or a doped ferrite layer. The method comprises the production of a bottom layer of titanium (Ti) or titanium oxide (TiOₓ) the thickness of which is preferably greater than or equal to eight nanometres; and then the production of a spinel iron oxide layer on said bottom layer.

When developing the present invention, it was found that the spinel iron oxide layer has an excellent texturing when it is deposited onto a bottom layer of titanium (Ti) or titanium oxides (TiOₓ).

Surprisingly, such texturing of the spinel iron oxide layer along the [111] direction is obtained whereas the bottom layer has no preferred crystal orientation along the [111] direction. Obtaining a face-centered cubic structure for the spinel iron oxide layer from a bottom layer having a very different crystallographic structure (hexagonal structure for titanium and tetragonal for TiO₂) is, of course unforeseeable. Besides, the mesh parameters of ferrite and of the bottom layer are little compatible, a priori, which makes the result of the invention even more surprising. It seems that such an excellent texturing is a natural tendency, with the grains of magnetite or maghemite arranging relative to the bottom layer of titanium (Ti) or titanium oxide (TiOₓ).

Then it is not necessary to provide a textured bulk substrate, such as an MgO substrate. Preparing a thin textured layer is not necessary either. The invention thus makes it possible to reduce or even eliminate the drawbacks of the known solutions to obtain a textured ferrite layer. More particularly, the nature of the Ti or TiOₓ layer is independent of the N-2 layer (the layer prior to the deposition of TiO₂), which makes it possible to insert such textured iron oxides at any stage of a conventional microelectronics process or during the production of complex structures of the MEMS type. Demonstrations have been made on an amorphous and crystalline underlayer.

The cost of production for such a layer is thus significantly reduced.

Besides, texturing the ferrite layer obtained with the invention does not depend much on the preferred orientation of the bottom layer, which still makes it possible to reduce the constraints of the method.

Much advantageously, the method according to the invention is not very sensitive to the conditions of the deposition of the spinel iron oxide layer and the bottom layer. The invention thus makes it possible to widen the scope of the method.

Advantageously too, the invention does not depend much on the materials underlying the bottom layer. It can thus be implemented in many devices.

Another very advantageous aspect lies in that the texturing power conferred by the bottom layer is obtained even though there is no direct contact between the latter and the spinel iron oxide layer. Even better, such texturing power is little dependent on the nature of the intermediate layer in contact with ferrite, so long as this intermediate layer is not amorphous. This makes it possible to use various intermediate materials, for instance conductive materials or on the contrary insulating materials, in order to meet the constraints of the concerned application.

Advantageously too, the method of the invention does not require the application of high temperatures to obtain the textured ferrite layer. This method is thus totally compatible with the current techniques in the CMOS microelectronics industry.

Optionally, the method according to the invention may also have at least any one of the following characteristics:
Advantageously, the thickness of the bottom layer is greater than or equal to 10 nanometres, preferably greater than or equal to 15 nanometres and more preferably greater than or equal to 20 nanometres. The thickness is measured along a direction perpendicular to the main faces of the substrate whereon the various layers are positioned. If the bottom layer has disk-shaped faces, the thickness thereof is then measured perpendicularly to such faces.
According to one embodiment, the spinel iron oxide layer is a layer of magnetite (Fe₃O₄) or a layer of maghemite (Fe₂O₃) or a layer formed of a mixture of magnetite (Fe₃O₄) and maghemite (Fe₂O₃). According to another embodiment, the layer of spinel iron oxide is a layer of doped magnetite or maghemite. Advantageously, the spinel iron oxide layer is a layer of magnetite or of maghemite doped with:
transition metals such as, for example: manganese (Mn), zinc (Zn), titanium (Ti), cobalt (Co), copper (Cu), cadmium (Cd),
metals belonging to the alkaline earths such as for example magnesium (Mg),
alkaline metals such as, for example: lithium (Li), sodium (Na) and lithium (Na with Li).
Or still doped with at least one among the following elements: chromium (Cr), nickel (Ni), tantalum (Ta), tungsten (W), rhenium (Re), osmium (Os), iridium (Ir), platinum (Pt), and/or (Au).
According to an advantageous embodiment, the bottom layer is produced by physical vapour deposition (PVD).
According to an advantageous embodiment, the production of the spinel iron oxide layer comprises chemical vapour deposition (CVD). Preferably, the production of the spinel iron oxide layer comprises chemical vapour deposition from metalorganic precursors (MOCVD).
Preferably, the production of the spinel iron oxide layer comprises chemical vapour deposition at a deposition temperature of less than 450° C.
According to an advantageous embodiment, the bottom layer is in contact with the spinet iron oxide layer. Then there is no intermediate layer between the spinel iron oxide layer and the bottom layer.
According to another advantageous embodiment, the method comprises, prior to the producing of the spinel iron oxide layer, a step of producing at least one intermediate layer on the bottom layer so that the intermediate layer is positioned between the bottom layer and the spinel iron oxide layer after producing the spinel iron oxide layer.
Advantageously, the intermediate layer is a layer of aluminium (Al), platinum (PI), or molybdenum (Mo).
Advantageously, the intermediate layer has a thickness of less than 100 nanometres. The invention is also advantageous in that it can be applied to a very wide range of thicknesses for this layer.
Preferably, the intermediate layer is in contact with the bottom layer and in contact with the spinel iron oxide layer.

Another aspect of the present invention relates to a microelectronic device comprising a spinel iron oxide layer preferably textured along the spinel iron oxide layer growth [111] axis, with the spinel iron oxide layer being a ferrite layer or a doped ferrite layer. The device comprises a bottom layer of titanium (Ti) or titanium oxide (TiOₓ) the thickness of which is preferably greater than or equal to eight nanometres and whereon the spinel iron oxide layer is positioned.

Optionally, the device according to the invention may also have one of the following characteristics:
According to an advantageous embodiment, the bottom layer is in contact with the spinel iron oxide layer.
According to another embodiment, the device comprises at least one intermediate layer positioned between the bottom layer and the spinel iron oxide layer.
Advantageously, the distance between the bottom layer and the spinel iron oxide layer is smaller than or equal to 100 nanometres. The invention is also advantageous in that it can be applied to a very wide range of distances.
Advantageously, the device is so configured as to be used as a microbolometer or ferroelectric random access non volatile memories (FeRAM), or conductive-bridging resistive memories (CBRAM), or micromechanical or electromechanical systems (MEMS, NEMS) or optic, optoelectronic (MOEMS), or spintronic systems comprising at least one micro-electronic device according to the invention.

Another aspect of the present invention relates to a microbolometer or a ferroelectric random access non volatile memory (FeRAM), or a conductive-bridging resistive memory (CBRAM), or a micromechanical or electromechanical system (MEMS, NEMS) or an optic, optoelectronic (MOEMS), or spintronic system comprising at least one micro-electronic device according to the invention.

The other objects, characteristics and advantages of the present invention will appear upon reading the following description and referring to the appended drawings. It should be understood that other advantages can be incorporated herein.

### BRIEF DESCRIPTION OF THE FIGURES

The aims, objects, characteristics and advantages of the invention will be more easily understood upon reading the detailed description of an embodiment of the latter which is illustrated by the following appended drawings, wherein:

FIG. 1 shows, for reference, a diffractogram of a sample of not textured magnetite powder.

FIG. 2 shows the diffractogram of a sample of magnetite obtained from a titanium underlayer.

FIG. 3 shows the diffractogram of a sample of magnetite obtained from a titanium oxide underlayer.

FIG. 4 shows the diffractogram of a sample of magnetite wherein an intermediate layer of molybdenum has been introduced between the bottom layer made of titanium and magnetite.

FIG. 5 shows the diffractogram of a sample of magnetite wherein an intermediate layer of platinum has been introduced between the bottom layer made of titanium oxide and magnetite.

FIG. 6 is a picture obtained with transmission electron microscopy equipment of a section of a magnetite layer on a bottom layer made of titanium oxide.

The figures are given as examples and are not restrictive to the invention. They are principle schematic representations intended to facilitate the understanding of the invention and are thus not necessarily at the same scale as the practical applications. More particularly, the relative thicknesses of the various layers are not representative of reality.

### DETAILED DESCRIPTION OF THE INVENTION

It should be noted that in the present invention, the words <<on>>, <<is deposited over>> or <<underlying>> or the equivalent thereof do not mean <<in contact with>>. Thus, for instance, depositing a first layer onto a second layer does not necessarily mean that the two layers are directly in contact with each other, but this means that the first layer at least partially covers the second layer by being either directly in contact therewith or by being separated therefrom by at least another layer or at least another element.

The method of the invention applies to obtaining a layer of magnetite Fe₃O₄ or maghemite having a chemical composition Fe₂O₃ in its so-called gamma phase (γ-Fe₂O₃). The invention also relates to the layers made of a mixture of magnetite and maghemite. As will be mentioned more precisely in the description hereunder, it also covers the case where the ferrite layer is doped.

In the present patent application, a spinel iron oxide layer can also be called a spinel structure iron oxide layer. Spinel iron oxides have a face-centered cubic structure (CFC). The layer can be doped so long as the spinel structure (Face-centered cubic CFC) has not been modified.

For clarity and conciseness, within the scope of the present invention, “spinel iron oxide layer” will refer to: a layer of magnetite, a layer of maghemite, a layer of a mixture of magnetite and maghemite, a layer of doped maghemite and/or of doped magnetite.

In the description hereunder, the invention will be disclosed in greater details for the embodiments wherein the spinel iron oxide layer is a layer of one among magnetite or maghemite. However, all the characteristics and steps of the embodiments will be applicable to the embodiments wherein the spinel iron oxide layer is a layer of the other one among magnetite or maghemite or a layer of a mixture of magnetite and maghemite or still a layer of maghemite or magnetite or a mixture of magnetite and maghemite which is doped.

The method of the invention, which is disclosed hereafter, enables to provide ferrite in thin layers with a significantly marked crystallographic texturing. As discussed in the section on the state of the art, texturing here means the oriented feature of the crystallographic structure that such materials can acquire, opposite to the extreme case of a polycrystalline material having all the crystal orientations in an equivalent way, which is the ideal case for a powder. For instance, a powder may be composed of crystallized grains, but the grains of which are randomly oriented relative to each other. The two extreme cases of texturing are the single-crystal and the powder.

The method of the invention makes it possible to obtain a good texturing of the spinel iron oxide layer starting from a bottom layer made of titanium (Ti) or titanium oxide (TiOₓ or TiO₂).

The spinel iron oxide layer is deposited onto the bottom layer of titanium or titanium oxide (TiOₓ or TiO₂). This bottom layer, or underlayer is the key element of the correct texturing of these materials.

Such bottom layer enables a large implementation of the method and makes it possible to reproducibly maintain a good texturing, whatever the deposition technique used: for instance MOCVD or sputtering, as mentioned hereunder. Texturing is relatively little dependent on the conditions of deposition. The texturing power of the bottom layer is also independent of the previously deposited underlayers. These may be amorphous or crystalline. The texturing power of the bottom layer is also independent of the intermediate layers in direct contact with the ferrites insofar as the intermediate layer is not amorphous).

Magnetite and maghemite texturing reveals little dependency on the state of oxidation of the bottom layer, which is an advantage and gives additional flexibility to the implementation of the method. The insulating or conducting characteristics of titanium and the oxides thereof gives flexibility to the adaptation of the considered applications.

To obtain a good vapour phase deposition MOCVD, a bottom layer of Ti, TiOₓ or TiO₂ with a thickness of at least 8 nm is preferred. A thickness of at least 15 nm is preferably selected, which makes it possible to improve the quality and the reproducibility of texturing. From 20 nm, the texturing quality almost no longer increases with the increase in the thickness of the bottom layer.

According to a preferred but not restrictive embodiment, the production of a spinel iron oxide layer uses a method currently used by the microelectronics industry which is the vapour phase chemical deposition from gaseous precursors, which are, in this preferred case, metalorganic precursors (MO). This technique is referred to by its acronym MOCVD. This method can easily be implemented and is not expensive.

The speed of the MOCVD deposition of magnetite and maghemite may be high. It typically ranges from 10 to 100 nm/minute. The morphology of the thin film and the stoichiometry thereof may be adjusted during the deposition.

The method of the invention is perfectly adapted to industrial use and enables a good compromise, which reconciles the crystal quality of the deposited material, the cost of production and the rate of production thereof.

For this purpose, the method preferably uses iron pentacarbonyl (Fe(CO)₅) as a precursor. This precursor requires a reactive gas of oxygen (O₂) to be used for forming the iron oxides. The deposition temperatures then range from the decomposition limit of the precursor which is above 150° C. and an upper limit which will mainly depend on the capacity of the underlying circuit to support high temperatures without damage. Typically, for a CMOS circuit, the limit is 450° C. Besides, it should be noted that, with a high temperature, the formation of haematite occurs, depending on the selected precursor, which must be avoided. It has been observed that this temperature is above 500° C. with iron pentacarbonyl (Fe(CO)₅) mentioned above and varies as a function of the selected oxygen rates. The lower limit for temperature is fixed by the precursor itself. It is typically 200° C. for Fe(CO)₅ even though, from 150° C. a partial decomposition can be observed. It should be noted that the above-mentioned temperatures can be very different if another precursor is used. For example the decomposition temperature of Fe(C₅H₅)₂ is 400° C. and that of FeO₆C₁₈H₂₇ is 140° C. Such temperatures are not restrictive, however. An increase in temperature is a favourable factor for the texturing of the spinel iron oxide layer. However, the temperature beyond which haematite would be formed should not be exceeded. The deposition temperature is thus mainly chosen according to the constraints imposed by the layers underneath the spinel iron oxide layer, for instance. To summarize, temperature is chosen so that magnetite is preserved and it causes no damage to the underlying circuit.

The pressure inside the enclosure amounts to a few milliTorr to a few Torr.

A preferred texturing marked in the [111] direction of the ferrites has been observed for a wide range of deposition temperature ranging from 300° C. to 450° C. This preferred crystal orientation in the [111] direction is also noted for a large range of pressures, typically between 30 milliTorr and a few Torr.

The bottom layer made of Ti is formed by physical vapour phase deposition or PVD. The deposition conditions may be within a range of temperature from the ambient temperature to 450° C. It should be noted that the microelectronics industry knows how to implement PVD type Ti deposition in a range of temperature from −20° C. to 480° C.

The deposition power may vary between 200 Watts and 12 kiloWatts. Using low power and temperatures for the deposition favours the forming of small grain thin layers, which is advantageous for Ti oxidation.

The objective is identical, whether for the deposition of pure Ti or Ti intended for forming TiOₓ or TiO₂. To form Ti oxides, a second step is necessary: the oxidizing annealing. The deposited Ti layer is then submitted to an oxidizing annealing, typically between 350° C. and 750° C. (less than 450° C. for a CMOS application) depending on the desired type of TiOₓ. It should be noted that, between 300° C. and 750° C., rutile TiO₂ is obtained. At lower temperatures, a material less oxidized or oxidized only in surface, rather than the TiOₓ type can be obtained. At a higher temperature, the risk is that phase may change: anatase, without it being a limit to the selection of temperature however. The annealing temperature also conditions the main crystal orientation which is (100) for low temperatures and (101) for high temperatures. TiOₓ or TiO₂ formed directly during the deposition (for example by sputtering Ti with O₂ as a reactive gas or MOCVD of Ti with O₂ as a reactive gas) would give the same results.

It should be reminded that the preferred crystal orientation of the spinel iron oxide layer is surprisingly less dependent, or even not at all dependent on the preferred crystal orientation of the bottom layer. Indeed, a spinel iron oxide layer having a preferred crystal orientation in the [111] direction is obtained whereas the bottom layer may have a (100) or (101) texture for instance. In addition, crystalline systems may be different; Fe₃O₄ has a face-centered cubic structure whereas rutile TiO₂ has a quadratic (tetragonale) structure.

The characterisation technique chosen to study the texturing of the material is X-ray diffraction (DRX).

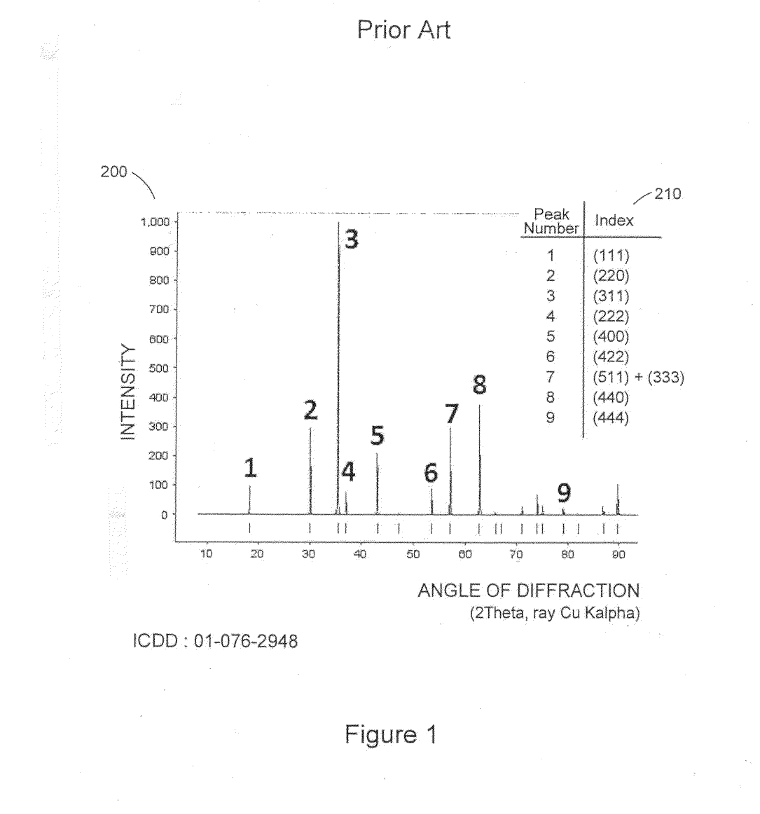

FIG. 1 shows, for reference, a diffractogram 200 of a sample of not textured magnetite powder. Such diagram conventionally shows, in this type of analysis, the intensity of the reflection peaks obtained, on the axis of ordinates, versus, on the axis of abscissae, the diffraction angle (2θ) of the X ray beam. It should be noted that 2θ is the retrieved angle (angle between the incident beam and the diffracted beam), θ is the incident angle which the sample is exposed to, i.e. the angle formed by the beam with the surface of the sample. As shown in FIG. 1, the person skilled in the art can determine, according to the angular position of the peaks, the Miller indices 210 of the crystalline planes corresponding to the analysed crystalline structure. A large distribution of the crystal orientations is of course found for the not textured magnetite powder of this sample. It can be noted that the reference diffractogramm of maghemite is very close to that of magnetite. A slight shifting of the peaks in 2Theta (resulting from the slight difference in the mesh parameter), or even some superlattice peaks can be observed, only. Generally speaking, magnetite can hardly be differentiated from maghemite in X ray diffraction.

It should be noted as from now that, with this type of indication, Miller indices multiple of each other correspond to identical crystalorientations. For example, the indices (444), (333) and (222) have the same crystal orientation as the (111) index, i.e. the growth [111] direction.

More precisely, the relationship between the lines or reflection peaks (111), (222), (333) and (444) is obtained using Bragg law as follows:

nλ=2(d(hkl) sin θ),

where n is an integer, called the reflection order
λI is the wavelength of the incident X-wave
d(hkl) is the interreticular spacing for given hkl index levels
θ is Bragg angle

As regards the line or reflection peak 111 diffraction order 2 (n=2) then:

2λ=2d(111) sin θ

λ=2(d(111)/2) sin θ

λ=2d(222) sin θ

This implies the existence of all these lines, since there is no condition for the extinction thereof according to the hkl indices planes having the same parity. In the case of a crystalline structure of the <<face-centered cubic>> type the indices planes (111) or (200) diffract but, for instance, the orientation (210) does not.

The lines (111), (222), (333) and (444) come from the same crystallites and their presence reveals a geometric factor inherent in Bragg law only.

Within the scope of the present invention, the growing [111] direction, also called the preferred crystal orientation in the [111] direction, implies the appearance of lines (111), (222), (333) and (444) etc. The (111) planes are stacked perpendicularly relative to the normal to the surface of the substrate (or growth direction).

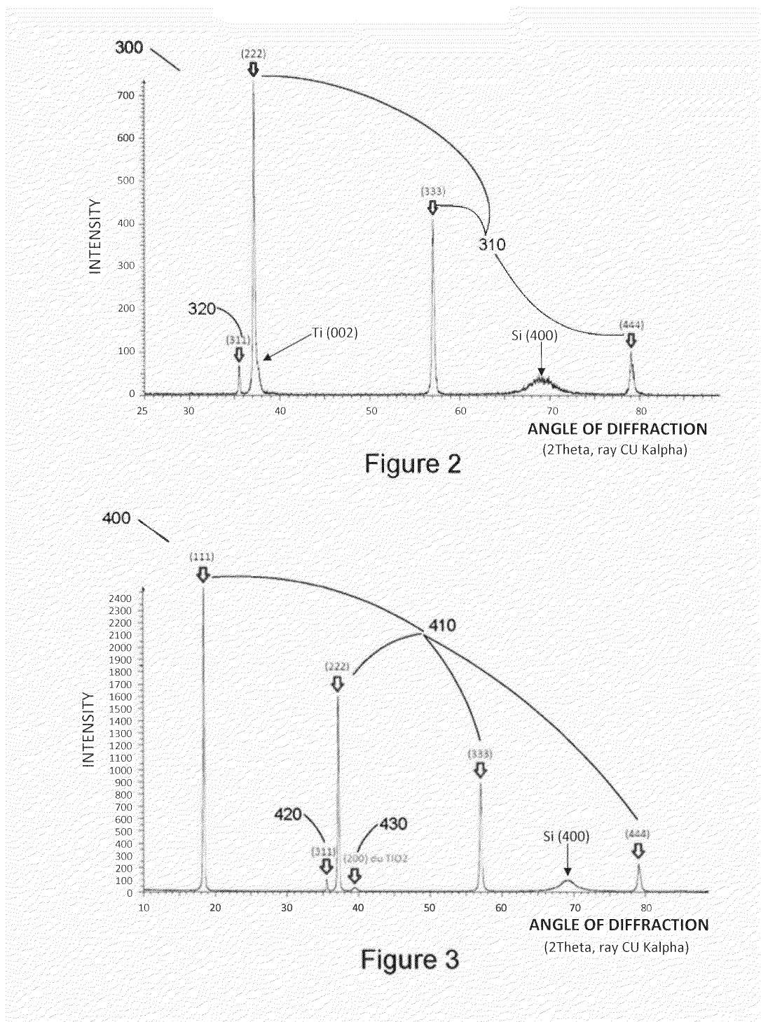

It is important to compare the diffractograms of the following Figures, experimentally obtained with the method of the invention, with the reference shown in FIG. 1. As a matter of fact the reference diffractogram shows the distribution of the peak intensity in the case of a powder sample, i.e. all the crystal orientations of which are potentially present in substantially identical proportions. As regards the diffracting volume, there are as many grains oriented in the [111] direction as grains oriented in the [311] direction. This makes it possible to take the structure factor of each line into account. The intensity of the diffracted beam is thus disclosed by a mathematical expression relating the coordinates of the mesh atoms, their electronic diffusion factor h, k, l indices of the planes family in the diffraction position (Miller indices). What is important is to compare the evolution of the distribution of the intensity of peaks present in the diffractograms of the following figures (FIGS. 2 to 5) with the reference diffractogram (FIG. 1), and thus to determine whether a crystal orientation dominates the other ones in spite of some uncertainties inherent in the analysis of textured thin films which might remain.

As disclosed in details in the following, the diffractograms of FIGS. 2 to 5 very distinctly show that the (111) orientation is dominating relative to the (311) orientation which is the most intense line for a powder.

FIG. 2 shows the diffractogram 300 of a sample of magnetite obtained from a (101)-oriented bottom layer of titanium (Ti) having a thickness of 20 nm. It can be seen that the layer of magnetite deposited above, on a thickness of 230 nm acquires the same crystal orientation 310 which is the main orientation (111) since, as noted above, the lines with the indices (222), (333) and (444) are equivalent. Only one different line (311) having a low intensity 320 appears in this diagram.

The fact that the line (111) cannot be found on the diffractogram of FIG. 2, whereas the lines (222), (333) and (444) are visible is only the result of the selected scanning angular range and the angle of diffraction measured which is traditionally noted 2θ. The line (111) of the ferrites deposited according to the method of the invention is positioned at 18.29°, using the Kalpha line of copper, a material the anode of the diffraction device used is made of. This results in that, for an angular measure range in 2θ between 25° and 89° it shall not be visible even though the corresponding orientation does exist.

FIG. 3 shows the diffractogram 400 of another sample of magnetite obtained from an (100)-oriented bottom layer of titanium oxide (TiO₂) having a thickness of 20 nm. It should be noted here too that the magnetite layer which has been deposited on the top, on a thickness of 230 nm does acquire the same crystal orientation 410 which mainly occurs in the (111) orientation. As mentioned above, only one different line (311) having a low intensity 420 appears in this diagram. The presence of a peak 430 having a very low intensity corresponding to the TiO₂ of the underlayer should also be noted.

It should also be noted that the midway width, or FWHM, the acronym for <<full width at half maximum>>, of the (111) peak for the magnetite deposited on TiO₂ is equal to 2.15° (as determined using a so-called <<rocking curve>> analysis, during which a tilting motion is applied to the sample), which is a very low value for a polycrystalline film deposited under these conditions. This suggests that the crystallites, in addition to texturing in the (111) orientation, are not much affected as regards their orientation relative to the plane of the sample surface.

It has also been advantageously noted that an intermediate layer, deposited on Ti, TiO₂ or more generally TiOₓ adopts the reticular parameters of this bottom layer and makes it possible to keep an excellent texturing of the spinel iron oxide layer.

The intermediate layer is preferably in contact, by one of its faces, with the bottom layer, and by the other face with the spinel iron oxide layer. The intermediate layer has no upper and no lower limit as regards thickness. The intermediate layer is preferably produced by PVD.

According to an alternate solution, several intermediate layers are positioned between the bottom layer and the spinel iron oxide layer, insofar as these concern crystalline materials the crystalline parameters of which are close.

Preferably, the intermediate layer is formed of at least one of the following materials: molybdenum (Mo), platinum (Pt), Aluminium (Al). All the not crystallized, and thus amorphous materials, may be excluded.

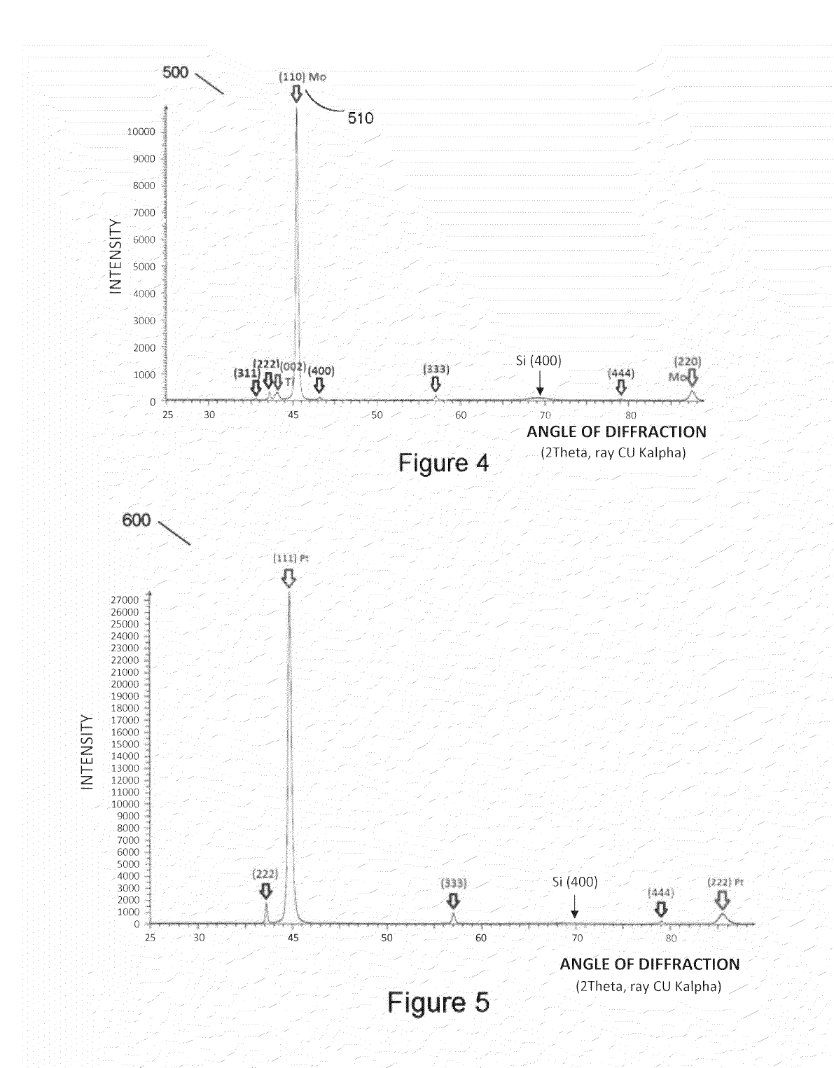

The diffractograms of FIGS. 4 and 5 show the results of the texturing of the spinel iron oxide layer obtained with an intermediate layer between the bottom layer and the spinel iron oxide layer.

FIG. 4 shows the diffractogram 500 of a sample of magnetite wherein an intermediate layer has been introduced between the bottom layer made of titanium (Ti) and the magnetite. In this case, the intermediate layer is molybdenum (Mo). Molybdenum is textured with an (110) orientation by the underlying titanium layer having an orientation 001. The magnetite underlayer has a thickness of 230 nm on a molybdenum and titanium underlayer having a thickness of respectively 50 nm and 20 nm. The preferred orientation of molybdenum has a peak 510 strongly marked with an (110) orientation.

FIG. 5 shows the diffractogram 600 of a sample of magnetite wherein an intermediate layer of platinum (Pt) has been introduced, in this case between the bottom layer of Titanium oxide (TiO₂) and magnetite. Platinum is textured with an (111) orientation by the underlying titanium layer having an (101) orientation. The magnetite underlayer has a thickness of 230 nm on a platinum and titanium oxide underlayer having a thickness of respectively 50 nm and 20 nm.

It can be noted that the crystalline texturing of magnetite is strongly marked in the [111] direction. This excellent texturing is confirmed by a very low FWHM of 2.15° seen on the <<rocking curve>> of the (111) peak of magnetite vs TiO_{2.} It should be reminded here that (111) and (222) come from the same grains. The angular value of 2.15° is a very good value which means that an important volume of crystallites (grains) have their (111) planes sloping by 2.15° or less relative to the surface of the sample which is perpendicular to the growing direction.

A highly textured magnetite layer is also obtained, which has a preferred crystal orientation in the [111] direction using a bottom layer of titanium Ti and an intermediate layer of aluminium (Al).

Aluminium and platinum have <<face-centered cubic>> structures the mesh parameter of which is equal to half that of Fe₃O₄, within a few percents. The following table illustrates the results of the texturing obtained with and without the bottom layer. The result is that the addition of the bottom layer significantly improves the texturing of magnetite.

| Stacking | FWHM of the | Preferred | Other orientations |
|---|---|---|---|
| used | Rocking Curve | orientation | noted |
| Fe₃O₄/Al | 2.6° | (111) | (111) only |
| (111)/Ti/SiO₂ | | | |
| (amorphous)/Si | | | |
| Fe₃O₄/Al | High (above 8°) | (111) | (311) of the Fe₃O₄, |
| (111)/SiO₂ | | | the crystalquality of Al |
| (amorphous)/Si | | | is also reduced |
| Fe₃O₄/Pt | 2.5° | (111) | (111) only |
| (111)/TiO₂/SiO₂ | | | |
| (amorphous)/Si | | | |
| Fe₃O₄/Pt | 5.2° | (111) | (311) of the Fe₃O₄, |
| (111)/SiO₂ | | | the crystalquality of Pt |
| (amorphous)/Si | | | is also reduced |

It should also be noted that the texturing bottom layer must, in any case, have a minimum thickness to be efficient. Typically, a thickness above 8 nm and preferably above 10 nm ensures a good texturing of ferrite.

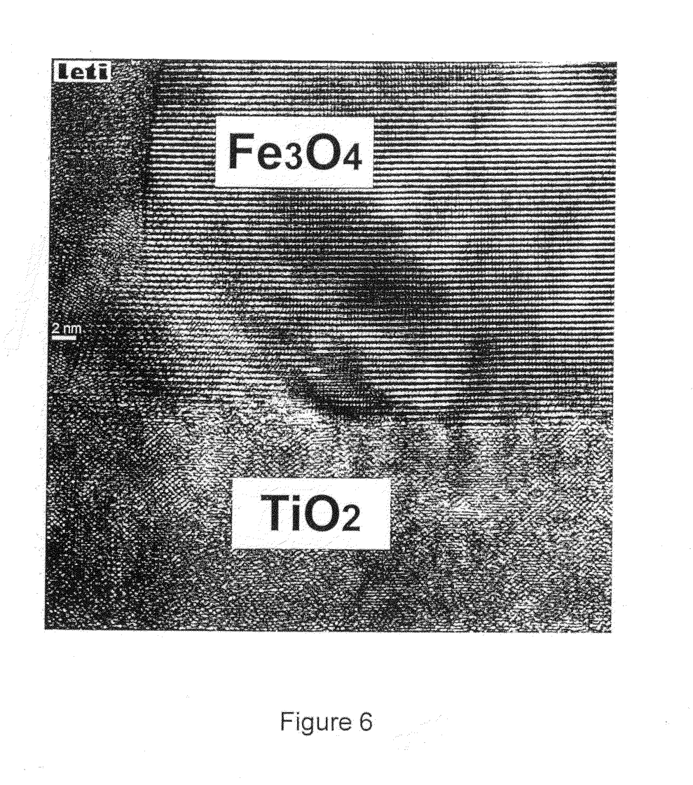

It should be noted that the magnetite obtained has a polycrystalline nature as shown in FIG. 6 which has been made using <<transmission electron microscopy>> or TEM equipment. This method reveals a large majority of large grains, having the same crystalorientation. As a matter of fact, this figure shows the planes parallel to the TiO₂ surface of magnetite which are well crystallised: no breaking has occurred at the stacking and this stack is kept clean and parallel.

The invention also extends to doped ferrites. As a non restrictive example, an excellent texturing in the [111] direction is obtained with layers of CoₓFe₃₋ₓO4 and NiₓFe₃₋ₓO4.

Several dopants can be considered, among which: manganese (Mn), zinc (Zn), chromium (Cr), nickel (Ni), titanium (Ti), cobalt (Co), tantalum (Ta), tungsten (W), rhenium (Re), osmium (Os), iridium (Ir), platinum (Pt), gold (Au).

Dopants may be present in very small, or even infinitesimal quantities, up to very high values, above atomic 30%. If D is the doping element, doping is most often noted DxFe3-xO4 with, in general, x ranging from 0 to 1, for instance x=0.5. The value of x may sometimes be above 1. From a few percents, this doping can be detected by EDX, the acronym for <<energy dispersive X-ray spectrometry>> using a MEB or TEM microscope. For smaller quantities, a large number of techniques are available to access stoichiometry: by secondary ion mass spectrometry or SIMS; or by Rutherford backscattering spectrometry or RBS. An evolution of stoichiometry can also be noted according to the variation in the mesh parameter by integrating elements having a different atomic radius which will modify the dimensions of the crystalline mesh.

Besides, if the experiment results have been established using samples obtained by MOCVD type chemical vapour deposition, all the deposition methods used by the microelectronics industry are likely to be used for obtaining the ferrite layer. More particularly, so-called IBD and PLD techniques, mentioned above, are liable to be suitable, as well as magnetron cathodic sputtering and physical vapour phase deposition or PVD.

As another alternative to a deposition by MOCVD, a sputtering deposition technique can be used, by sputtering a target with iron or a target with dopant, for instance a target made of nitride or cobalt, by Argon plasma and dioxygen. The following conditions may be foreseen:
Temperature of the substrate: between the ambient temperature and 700° C. for instance
Sputtering power around 30 W
Pressure of less than 10⁻³ mbar
From 2 to 5% of oxygen with respect to Argon.

It should also be noted that the deposits of the MOCVD type used for forming the ferrite layer revealed that the method parameters, such as temperature, pressure etc. only slightly affect the texturing of ferrite. On the contrary it is the bottom layer made of Ti or the oxides thereof which is the key element for texturing the ferrites layer.

It should also be noted that the films of textured magnetite and maghemite potentially interest many other fields such as spintronics, magnetism, so-called FeRAM non volatile memories, electromechanical microsystems or MEMS.

Eventually, it should be noted that the bottom layers of titanium and titanium oxides are responsible for the excellent crystallographic texturing of the magnetite obtained and that the conditions of the magnetite deposition are secondary. It has been noted that the grains of magnetite naturally arrange with respect to the bottom layer made of Ti, TiOx or TiO₂. The texturing power of such bottom layers is independent of the layers deposited before the bottom layer and the intermediate layers in direct contact with the ferrites. This is a particularly advantageous characteristic of the method of the invention. Another advantage is that the preferred orientation of this underlayer has little, or even no effect on the (111) texturing of ferrite.

The results obtained with magnetite can be extrapolated to maghemite which has a very similar crystalline structure. The change of phase between magnetite and maghemite is a topotactic reaction. A mixture of magnetite/maghemite can thus be obtained without the crystalline structure of the thin film and the preferred orientation of these grains being changed. It should be noted that it is possible to switch from magnetite to maghemite using an oxidizing annealing of magnetite.

The invention is not limited to the embodiments described above and extends to all the embodiments covered by the following claims.

1. A method for producing a spinel iron oxide layer, textured according to a preferred crystal orientation along the [111] direction, the method comprising:
producing a bottom layer of titanium (Ti) or titanium oxide (TiOx), wherein a thickness of the bottom layer is greater than or equal to eight nanometres; and then
producing a spinel iron oxide layer on the bottom layer produced beforehand.

2. The method according to claim 1, wherein the thickness of the bottom layer is greater than or equal to 10 nanometres.

3. The method according to claim 1, wherein the spinel iron oxide layer is a layer of magnetite (Fe₃O₄) or a layer of maghemite (Fe₂O₃) or a layer formed of a mixture of magnetite (Fe₃O₄) and maghemite (Fe₂O₃).

4. The method according to claim 1, wherein the spinel iron oxide layer is a layer of doped magnetite (Fe₃O₄) or a layer of doped maghemite (Fe₂O₃) or a layer formed of a mixture of magnetite (Fe₃O₄) and maghemite (Fe₂O₃), wherein the mixture is doped.

5. The method according to claim 4, wherein the doping element is selected from the group consisting of (Mn), zinc (Zn), chromium (Cr), nickel (Ni), titanium (Ti), cobalt (Co), tantalum (Ta), tungsten (W), rhenium (Re), osmium (Os), iridium (Ir), platinum (Pt), gold (Au), titanium (Ti), copper (Cu), cadmium (Cd), magnesium (Mg), lithium (Li), chromium (Cr), nickel (Ni), and tantalum (Ta).

6. The method according to claim 1, wherein the bottom layer is produced by physical vapour deposition (PVD).

7. The method according to claim 1, wherein the production of the spinel iron oxide layer comprises chemical vapour deposition (CVD).

8. The method according to claim 7, wherein the production of the spinel iron oxide layer comprises a chemical vapour deposition with metalorganic precursors (MOCVD).

9. The method according to claim 1, wherein the production of the spinel iron oxide layer comprises a chemical vapour deposition at a deposition temperature of less than 450° C.

10. The method according to claim 1, wherein the bottom layer is in contact with the spinel iron oxide layer.

11. The method according to claim 1, comprising, prior to the producing of the spinel iron oxide layer, producing intermediate layer on the bottom layer so that the intermediate layer is positioned between the bottom layer and the spinel iron oxide layer after producing the spinel iron oxide layer.

12. The method according to claim 11, wherein the intermediate layer is a layer of aluminium (Al) or platinum (Pt), or molybdenum (Mo).

13. The method according to claim 11, wherein the intermediate layer is in contact with the bottom layer and in contact with the spinel iron oxide layer.

14. A microelectronic device, comprising a spinel iron oxide layer textured along a [111] growth axis, with the spinel iron oxide layer being a ferrite layer or a doped ferrite layer, wherein the spinel iron oxide layer comprises a bottom layer of titanium (Ti) or titanium oxide (TiOx), a thickness of which is greater than or equal to eight nanometres and whereon the spinel iron oxide layer is positioned.

15. The device according to claim 14, wherein the bottom layer is in contact with the spinel iron oxide layer.

16. The device according to claim 14, comprising a intermediate layer positioned between the bottom layer and the spinel iron oxide layer.

17. A device configured to be adapted for a microbolometer or ferroelectric random access non volatile memories (FeRAM), conductive-bridging resistive memories (CBRAM), micromechanical or electromechanical systems (MEMS, NEMS) or optic, optoelectronic (MOEMS), or spintronic systems and comprising a micro-electronic device according to claim 14.

18. The method according to claim 1, wherein the thickness of the bottom layer is greater than or equal to 15 nanometres.

19. The method according to claim 1, wherein the thickness of the bottom layer is greater than or equal to 20 nanometres.
